(19) United States
(12) Patent Application Publication
(10) Pub. No.: US 2025/0194131 A1
(43) Pub. Date: Jun. 12, 2025

(54) Method for Forming a Semiconductor Device

(71) Applicant: IMEC VZW, Leuven (BE)

(72) Inventors: Anabela Veloso, Leuven (BE); Roger Loo, Leuven (BE); Geert Eneman, Heverlee (BE)

(21) Appl. No.: 18/969,195

(22) Filed: Dec. 4, 2024

(30) Foreign Application Priority Data
Dec. 6, 2023 (EP) 23214717.3

(51) Int. Cl. H10D 30/01; H10D 62/00

(52) U.S. Cl. CPC H10D 30/0198; H10D 62/021

(57) ABSTRACT

There is provided a method for forming a semiconductor device. The method comprising performing frontside processing comprising forming a transistor structure on a frontside of a substrate, the transistor structure comprising a first source/drain body and a second source/drain body located in a first and a second source/drain region, respectively, and a channel structure between the first source/drain body and the second source/drain body, wherein the first source/drain body and the second source/drain body have a first doping concentration. The method also includes, subsequent to the frontside processing, performing backside processing comprising exposing the first source/drain body from a backside of the substrate, and processing the first source/drain body to form, in the first source/drain region, a replacement source/drain body having a second doping concentration different from the first doping concentration.

### CROSS-REFERENCE TO RELATED APPLICATIONS

The present application is a non-provisional patent application claiming priority to European Patent Application No. 23214717.3, filed Dec. 6, 2023, the contents of which are hereby incorporated by reference.

### FIELD OF THE DISCLOSURE

The present disclosure generally relates to a method for forming a semiconductor device.

### BACKGROUND

The use of high mobility channel materials has long attracted great interest in the semiconductor industry since high mobility channel materials have a bulk mobility exceeding that of Si which is the commonly used channel material. For example, Ge has a bulk mobility which is 4.4 times higher for holes and 2.4 times higher for electrons as compared to Si. Such high bulk mobility generally results in a high drivability with high on-state currents, ION, of for example Ge FETs. However, such high mobility channel material devices may suffer from (e.g., significantly) higher band-to-band-tunneling, BTBT (e.g., owing from their small bandgap), and thus higher off-state leakage currents, IOFF. Hence, it would be useful to manufacture high mobility channel material devices which exhibit lower off-state leakage currents while still having high drivability, and thus high on-state currents.

### SUMMARY

In light of the above, it is an object of the present disclosure to provide a method for forming a semiconductor device which mitigates at least some of the issues associated with high mobility channel material devices.

Hence, it is an object to provide a method for forming a semiconductor device which allows for formation of a high mobility channel material semiconductor device with a reduced off-state leakage current.

Another object is to provide a method for forming a semiconductor device which allows for formation of a high mobility channel material semiconductor device which has a high drivability, and hence a high on-state current, with a reduced off-state leakage current.

Another object is to provide a method for forming a semiconductor device which allows for formation of a high mobility channel material semiconductor device with a reduced contact resistance.

Another object is to provide a method for forming a semiconductor device which uses fewer process steps.

Another object is to provide a method for forming a semiconductor device which is less complex.

Another object is to provide a method for forming a semiconductor device which is more cost-effective.

These and other objects may be achieved by a method for forming a semiconductor device in accordance with the independent claim. Embodiments of the present disclosure are defined in the dependent claims.

Hence, according to an aspect of the present disclosure, there is provided a method for forming a semiconductor device, comprising performing frontside processing comprising forming a transistor structure on a frontside of a substrate, the transistor structure comprising a first source/drain body and a second source/drain body located in a first and a second source/drain region, respectively, and a channel structure between the first source/drain body and the second source/drain body, wherein the first source/drain body and the second source/drain body have a first doping concentration. The method further includes, subsequent to the frontside processing, performing backside processing comprising exposing the first source/drain body from a backside of the substrate, and processing the first source/drain body to form, in the first source/drain region, a replacement source/drain body having a second doping concentration different from the first doping concentration.

Thus, the present disclosure discloses that by processing the first source/drain body to form a replacement source/drain body which has a different doping concentration than the second source/drain body, an asymmetric semiconductor device, e.g., a device with an asymmetric doping of the source/drain bodies, may be formed. In some embodiments, an asymmetric high mobility channel material semiconductor device or high mobility device may be formed.

In this regard, in order to provide a high mobility device which offers high drivability and low off-state currents the device will may have a high source doping, which allows for high on-state currents, while at the same time have low drain doping, which allows for low off-state leakage currents.

Further, the present method may allow for forming an asymmetric high mobility channel material semiconductor device or high mobility device while using fewer process steps as compared to traditional methods. More specifically, by processing the first source/drain body during the backside processing, which (e.g., anyhow) may involve accessing the first source/drain body for contacting with a backside power delivery network, the asymmetric doping may be provided without adding additional process steps during the frontside processing. Accordingly, the present method may be useful in fabrication of a semiconductor device comprising a backside power delivery network.

Furthermore, the present method may allow for forming an asymmetric high mobility channel material semiconductor device or high mobility device in a less complex way at a reduced cost.

The first source/drain body and the second source/drain body may be a source body and a drain body, respectively. Alternatively, the first source/drain body and the second source/drain body may be a drain body and a source body, respectively. This applies correspondingly to the first and second source/drain regions.

In practice, in a case where the first source/drain body and the first source/drain region is a source body and a source region, respectively, the present method allows for forming an asymmetric device by increasing the doping concentration in the source region by forming the replacement source body with a higher doping concentration as compared to the concentration of the drain body.

Conversely, in practice, in a case where the first source/drain body and the first source/drain region is a drain body and a drain region, respectively, the present method allows for forming an asymmetric device by decreasing the doping concentration in the drain region by forming the replacement drain body with a lower doping concentration as compared to the concentration of the source body.

More generally, the present method allows for fabrication of an asymmetric device by increasing or decreasing the doping concentration in the first source/drain region while not affecting the doping concentration in the second source/drain region.

More specifically, the difference in doping concentrations between the replacement source/drain body and the second source/drain body is by the present method achieved by processing the first source/drain body to form, in the first source/drain region, a replacement source/drain body having a second doping concentration different from the first doping concentration. Thereby, an asymmetric transistor structure, e.g., a non-uniform transistor structure with asymmetric source drain doping is formed.

Thus, by forming the first source/drain body and the second source/drain body with a first doping concentration during frontside processing, and subsequently during backside processing, processing the first source/drain body to form a replacement source body having a second doping concentration different from the first doping concentration, the asymmetry of the formed semiconductor device may be tailored by tailoring the first and the second doping concentrations.

The “replacement source/drain body” may be a source/drain body having properties different from those of the first source/drain body which is formed during the frontside processing. In some embodiments, the replacement source/drain body may have a higher doping concentration as compared to the first source/drain body formed during the frontside processing, or, the replacement source/drain body may have a lower doping concentration as compared to the first source/drain body formed during the frontside processing.

The replacement source/drain body may comprise material from the first source/drain body formed during the frontside processing. The replacement source/drain body may comprise other material than the material of the first source/drain body formed during the frontside processing. Thus, the replacement source/drain body may for example be formed by altering the first source/drain body formed during the frontside processing. The replacement source/drain body may for example be formed by altering a portion of the first source/drain body formed during the frontside processing. The replacement source/drain body may for example be formed partially replacing the first source/drain body formed during the frontside processing. The replacement source/drain body may for example be formed replacing the first source/drain body formed during the frontside processing. The replacement source/drain body may for example be formed by adding material to the first source/drain body formed during the frontside processing. The replacement source/drain body may for example be formed by a combination of the above techniques.

According to some embodiments, processing the first source/drain body may comprise epitaxially growing doped source/drain material in the first source/drain region, which may be useful in that the replacement source/drain body may be formed by epitaxial material with a higher or lower doping concentration as compared to the first source/drain body. The replacement source/drain body may be formed with a higher doping concentration as compared to the first source/drain body by epitaxially growing doped source/drain material having a doping concentration higher than the first doping concentration. In this way, the overall or average doping concentration of the replacement source/drain body may be increased relative to the first and second source/drain bodies. Alternatively, the replacement source/drain body may be formed with a lower doping concentration as compared to the first source/drain body by epitaxially growing doped source/drain material having a doping concentration lower than the first doping concentration. In this way, the (e.g., overall or) average doping concentration of the replacement source body may be decreased relative to the first and second source/drain bodies.

According to some embodiments, the doped source/drain material may be grown on an exposed surface of the first source/drain body, which is useful in that the first source/drain body may be at least partly preserved in the first source/drain region. This may facilitate the processing since less material of the first source/drain body may be removed.

According to some embodiments, processing the first source/drain body may further comprise removing at least a portion of the first source/drain body (e.g., or at least a major portion of the first source/drain body) to form a source/drain body cavity in the first source/drain region, wherein the doped source/drain material subsequently is epitaxially grown in the source/drain body cavity. By removing at least a portion of the first source/drain body, a source/drain body cavity corresponding to a least a portion of the first source/drain body may be formed in the first source/drain region. By subsequently epitaxially growing the doped source/drain material in the source/drain body cavity, the resulting replacement source/drain body may be formed with the second doping concentration. The (e.g., effective) doping concentration of the composite replacement source/drain body (formed by the remaining portion of the first source/drain body and the epitaxial source/drain material) may be controlled by varying the amount of material removed from the first source/drain body. Similarly, by removing at least a (e.g., major) portion of the first source/drain body, a source/drain body cavity corresponding to a least a (e.g., major) portion of the first source/drain body may be formed in the first source/drain region. By subsequently epitaxially growing the doped source/drain material in the source/drain body cavity, the resulting replacement source/drain body may be formed with the second doping concentration. The second doping concentration may be provided in a greater part of the replacement source/drain body.

According to some embodiments, the first source/drain body may comprise a semiconductor liner provided at least at an interface between the first source/drain body and the channel structure, wherein the semiconductor liner is formed of a material different from a material of the first source/drain body, which is useful in that the liner may protect the channel structure during the backside processing. For example, the liner may protect the channel structure while forming the source/drain body cavity. Furthermore, the liner may protect the channel structure during the frontside processing.

According to some embodiments, the at least a portion (e.g., or the at least a major portion) of the first source/drain body may be removed using an etching process etching the material of the first source/drain body selective to the material of the semiconductor liner, which is useful in that the extension of the source/drain body cavity may be controlled by the presence of the liner. Further, the liner may prevent or counteract the channel structure from being affected by the etchants used for forming the source/drain body cavity.

According to some embodiments, exposing the first source/drain body may comprise thinning the substrate from the backside.

According to some embodiments, exposing the first source/drain body may comprise forming an opening in the substrate underneath the first source/drain body to expose the first source/drain body, wherein the first source/drain body is processed from the opening in the substrate.

According to some embodiments, forming the opening in the substrate may comprise thinning the substrate to expose a dummy contact plug provided underneath the first source/drain body, and removing the dummy contact plug to expose the first source/drain body.

According to some embodiments, the method may further comprise, subsequent to forming the opening in the substrate, forming an insulating liner covering the substrate and the exposed first source/drain body, and opening the insulating liner in the opening in the substrate to expose the first source/drain body, wherein the first source/drain body is processed from the opening in the insulating liner, which is useful in that the insulating liner may protect the substrate during the backside processing.

According to some embodiments, the doped source/drain material may be epitaxially grown via the opening in the insulating liner, which is useful in that the insulating liner may inhibit the doped source/drain material from growing at the substrate while being epitaxially grown via the opening in the insulating liner. The insulating liner may thus be used as an epitaxy mask inhibiting deposition of source/drain material in regions other than the first source/drain region.

According to some embodiments, the at least a portion (e.g., or the at least a major portion) of the first source/drain body may be removed by etching from the opening in the insulating liner, which is useful in that the insulating liner may prevent or counteract the substrate being affected by the etching. The insulating liner may thus be used as an etch mask when etching the first source/drain body.

According to some embodiments, exposing the first source/drain body may comprise removing the substrate underneath the transistor structure to expose the first source/drain body and the second source/drain body, forming a bottom isolation layer covering the first source/drain body and the second source/drain body, and forming an opening in the bottom isolation layer to expose the first source/drain body, wherein the first source/drain body is processed from the opening in the bottom isolation layer, which is useful in that the bottom isolation layer may protect the transistor structure while processing the first source/drain body from the opening in the bottom isolation layer.

According to some embodiments, the opening in the bottom isolation layer may be formed by removing a dummy contact plug provided underneath the first source/drain body, which is useful in that the opening in the bottom isolation layer may be formed in a self-aligned manner.

According to some embodiments, processing the first source/drain body may comprise increasing the doping concentration in the first source/drain body, and wherein increasing the doping concentration comprises implanting dopants into the first source/drain body, and/or diffusing dopants into the first source/drain body. The doping concentration in the replacement source/drain body may be increased by (e.g., selectively) introducing dopants in the first source/drain body (e.g., but not the second source/drain body).

According to some embodiments, the method may further comprise forming a source/drain contact on the replacement source/drain body, which is useful in that a reduced contact resistance may be achieved between the replacement source/drain body and the source/drain contact as compared to if the source/drain contact were to be formed on the first source/drain body.

According to some embodiments, the frontside processing may further comprise forming a source/drain contact on the second source/drain body.

According to some embodiments, the frontside processing may further comprise forming a gate stack on the channel structure.

According to some embodiments, the channel structure may comprise one or more layers of a Ge-comprising channel material.

According to some embodiments, the channel structure may comprise one or more layers of a SiGe-comprising channel material.

### BRIEF DESCRIPTION OF THE FIGURES

This and other aspects of the present disclosure will now be described in more detail, concerning the appended drawings showing example embodiments of the present disclosure.

FIGS. 1, 2, 3, and 4 schematically show a device structure at different stages of a method for forming a semiconductor structure.

FIG. 5 schematically shows how a replacement source/drain body may be formed according to embodiments.

FIGS. 6, 7, and 8 schematically show a device structure at different stages of a method for forming a semiconductor structure.

FIG. 9 schematically shows how a source/drain contact may be formed according to embodiments.

FIGS. 10, 11, 12, and 13 schematically show a device structure at different stages of a method for forming a semiconductor structure.

FIG. 14 schematically shows a device structure comprising a dummy contact plug.

FIG. 15 schematically shows a device structure in which the first source/drain body comprises a semiconductor liner.

The figures are schematic, not necessarily to scale, and generally show parts which are useful to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein, rather, these embodiments are provided by way of example. Furthermore, like numbers refer to the same or similar elements or components throughout.

Hereafter follows a detailed description of various method embodiments for forming a semiconductor device. More specifically, the methods comprise, subsequent to the frontside processing, performing backside processing including processing a first source/drain (S/D) body to form, in a first S/D region, a replacement S/D body having a doping concentration different from the doping concentration of the first S/D body. The methods will be described with reference to the drawings.

The drawings are schematic and the relative dimensions of some structures and layers may be exaggerated and not drawn to scale. Rather the dimensions may be adapted for illustrational clarity and to facilitate understanding. When present in the figures, the indicated axes X and Y refer to a horizontal or lateral direction, and a vertical direction, respectively. As used herein, the terms “horizontal” and “lateral” refer to directions parallel to (a main surface of) a substrate on/from which the semiconductor device being formed. The term “vertical” refers to a direction parallel to a normal (e.g., perpendicular) direction of (a main surface of) the substrate on/from which the semiconductor device being formed (e.g., transverse to the substrate). Further, the (e.g., positive) vertical direction refers to a direction which points out of what typically is regarded as a frontside of the substrate.

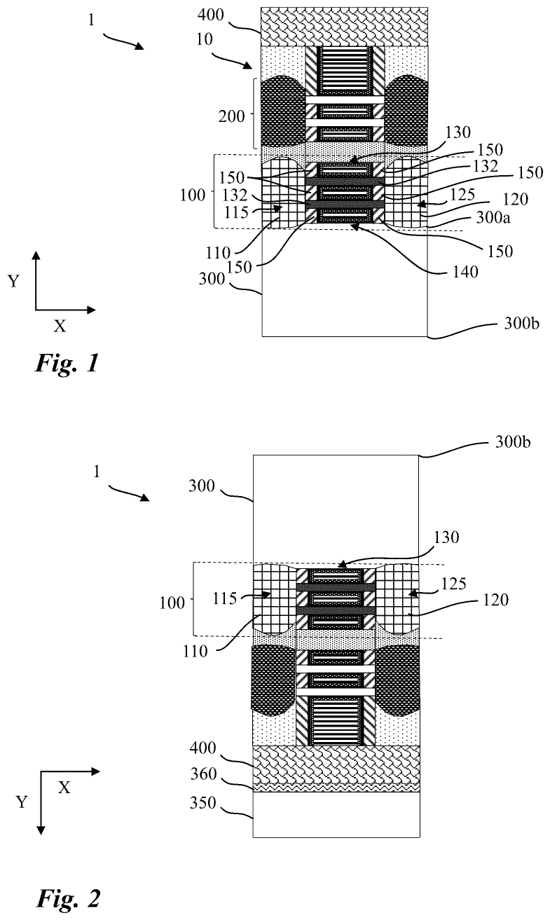

Referring FIG. 1, a transistor structure 100 according to example embodiments may be formed by performing frontside processing. In FIG. 1, the transistor structure 100 forms part of a complementary field effect transistor (CFET) structure 10 which may be formed performing frontside processing. The CFET structure 10 forms part of the device structure 1 depicted in FIG. 1. Hence, the device structure 1 includes the elements and structures depicted in FIG. 1. The device structure 1 will be described at different stages of method embodiments while referring to the drawings. A CFET may comprise a PMOS transistor structure 100 and a NMOS transistor structure 200 vertically stacked (e.g., on top of each other). In the following description, the transistor structure 100 located closest to the substrate 300 will be described, although the transistor structure 200 will also be illustrated throughout the drawings. The device structure or structure 1 of FIG. 1 further comprises structures 400 which are formed during middle-of-line (MOL) and back-end-of-line (BEOL) processes. Those structures 400 will also be illustrated throughout the drawings. However, the transistor structure 200 and the structures 400 are not be described in greater detail.

Further, the present disclosure is (e.g., equally) applicable to non-stacked semiconductor structures 100, such as non-stacked nanosheet-FET devices and fin-FET devices.

As depicted in FIG. 1, the transistor structure 100 has been formed on a frontside 300a of a substrate 300. The substrate 300 may be a conventional semiconductor substrate suitable for complementary FETs. The substrate 300 may be a single-layered semiconductor substrate, for example formed by a bulk substrate such as a Si substrate, a germanium (Ge) substrate or a silicon-germanium (SiGe) substrate. A multi-layered/composite substrate is however also possible, such as an epitaxially grown semiconductor layer on a bulk substrate, or a semiconductor-on-insulator (SOI) substrate, such as a Si-on-insulator substrate, a Ge-on-insulator substrate, or a SiGe-on-insulator substrate.

The transistor structure 100 comprises a first S/D body 110 and a second S/D body 120. The first S/D body 110 is located in a first S/D region 115. The second S/D body 120 is located in a second S/D region 125.

The first S/D body 110 and a second S/D body 120 may be formed by epitaxially growing the first S/D body 110 and a second S/D body 120. The first S/D body 110 and the second S/D body 120 may for example be formed by epitaxially growing doped Si, Si—C, SiGe, Ge, Ge—Sn, or SiGe—Sn.

A channel structure or channel region 130 is provided between the first S/D body 110 and the second S/D body 120. The depicted channel structure 130 comprises channel layers 132 in the form of nano-sheet channel layers 132. The nano-sheet channel layers 132 depicted in FIG. 1 extend between the first S/D body 110 and the second S/D body 120. In FIG. 1, (e.g., only) two nano-sheet channel layers 132 are illustrated for clarity although the channel structure 130 may comprise any number of channel layers 132. The channel layers 132 of the channel structure 130 may comprise a high mobility channel material. The channel layers 132 may, according to example embodiments, comprise one or more layers 132 of a Ge-comprising channel material. The channel layers 132 may, according to example embodiments, comprise one or more layers 132 of Ge as the channel material. The channel layers 132 may, according to example embodiments, comprise one or more layers 132 of a SiGe-comprising channel material. When the channel layers 132 comprise a SiGe-comprising channel material, the Ge concentration may be (e.g., substantially) equal to or above 70% in order to provide a high mobility channel. However, the present disclosure is also applicable for lower Ge concentrations. Similarly, the present disclosure is also applicable for Si-based channel materials.

Further, according to example embodiments, the channel structure 130 may comprise a single channel in channel region. Further, the channel structure 130 may comprise channels in form of nanowires.

The depicted channel layers 132 of the channel structure 130 are surrounded by a gate stack 140. The gate stack 140 is schematically drawn and may comprise a gate dielectric and one or more gate metal layers. The gate stack will not be described in greater detail here. However, it is to be understood that any type of suitable gate stack 140 may be used. Further, according to embodiments the gate stack 140 may be provided (e.g., directly) on top of the channel structure 130 e.g., in case of a single channel in the channel structure 130.

Further, the depicted gate stack 140 is separated from the first S/D body 110 and the second S/D body 120 by an inner spacer 150. The inner spacer 150 may be formed according to suitable techniques.

The first S/D body 110 and the second S/D body 120 have a first doping concentration. The first doping concentration may lie in the range of 1·1017-1·1022 dopants per cubic centimeter. The first S/D body 110 and the second S/D body 120 may be doped with P, As, Sb, Ga, or B. The first S/D body 110 and the second S/D body 120 may be formed (e.g., simultaneously) using the same processing steps to arrive at the first doping concentration.

FIG. 2 illustrates how the (e.g., complete) structure 1 of FIG. 1 has been bonded to a carrier substrate or wafer 350 by a bonding layer 360. The carrier substrate may be a silicon wafer. The bonding layer may be an oxide or nitride bonding layer, or any other conventional type of bonding layer suitable for CMOS-processing. Further, the (e.g., complete) structure has been flipped upside down, such that the substrate 300 which was depicted at the bottom in FIG. 1 is now located at the top as illustrated in FIG. 2. The flipping of the (e.g., complete) structure 1 is also indicated by the altered direction of the Y-axis in FIG. 2 in relation to FIG. 1. By bonding the (e.g., complete) structure 1 of FIG. 1 to the carrier substrate 350 and flipping the (e.g., complete) structure 1, the (e.g., complete) structure 1 is prepared for backside processing.

In the following, it will be described how the (e.g., complete) structure 1 of FIGS. 1 and 2 may be subjected to backside processing subsequent to being subjected to frontside processing. More specifically, it will be described how the first S/D body 110 of the transistor structure 100 may be exposed from a backside 300b of the substrate 300 and how the first S/D body 110 may be processed to form a replacement S/D body 112 in the first S/D region 115, where the replacement S/D body 112 has a second doping concentration which is different from the first doping concentration. It will be described how the replacement S/D body 112, which has a doping concentration different from the one of the first S/D body 110, is formed in the first S/D region 115 via backside processing of the transistor structure 100. As previously discussed, the first S/D body 110 may define a source body 110 and the second S/D body 120 may define a drain body, wherein a replacement source body 112 with a doping concentration different from (e.g., higher) than the original source body 110 may be formed. However, the first S/D body 110 may also define a drain body 110 and the second S/D body 120 may define a source body, wherein a replacement drain body 112 with a doping concentration different from (e.g., lower) than the original drain body 120 may be formed.

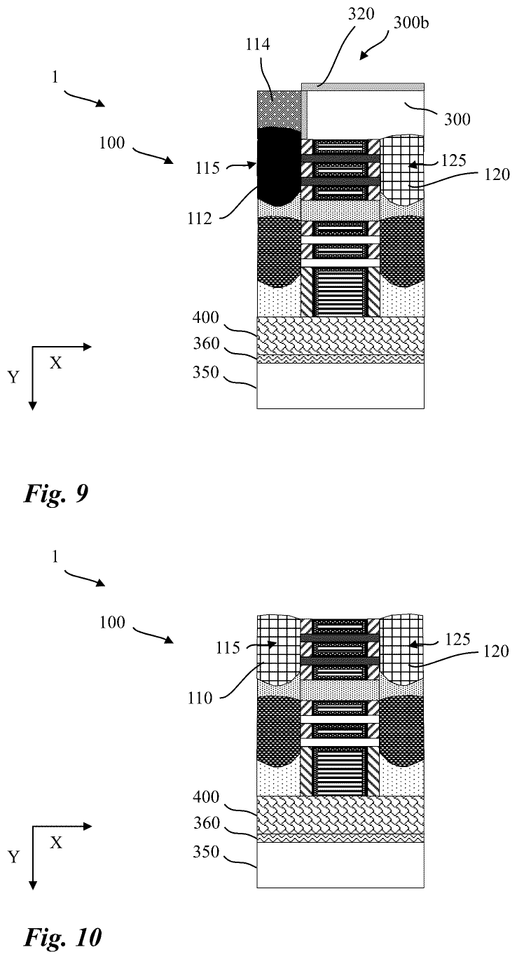

A first approach for forming a replacement S/D body 112 will be disclosed with reference to FIG. 1-5. A second approach for forming a replacement S/D body 112 will be disclosed with reference to FIG. 6-8 Thereafter, a third approach for forming a replacement S/D body 112 will be disclosed with reference to FIG. 10-13.

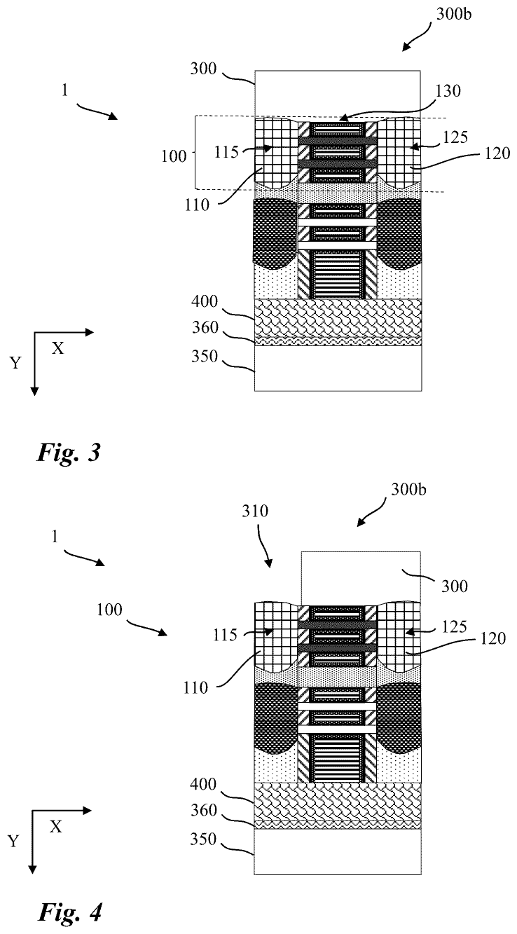

Now turning to FIG. 3, FIG. 3 illustrates how the substrate 300 has been subjected to thinning from the backside 300b thereof such that (e.g., only) a limited portion of the substrate 300 remains underneath the transistor structure 100. In practice, the substrate 300 may be thinned by grinding or chemical mechanical polishing (CMP), and/or etch back (e.g., anisotropic dry etching, wet etching, a gas chemical etch process like siconi or a certas type of process).

Now also turning to FIG. 4, an opening 310 has been formed in the substrate 300 is shown. The opening 310 exposes the first S/D body 110 from the backside 300b of the substrate 300 as depicted in FIG. 4. Thus, the opening 310 has been formed in the substrate 300 underneath the first S/D body 110 as illustrated in FIG. 4. The opening 310 may be formed in the substrate by conventional lithographic and etching processes. For example, a photomask may be formed on the backside of the thinned substrate 300 and used as an etch mask for forming the opening 310 in the substrate 300.

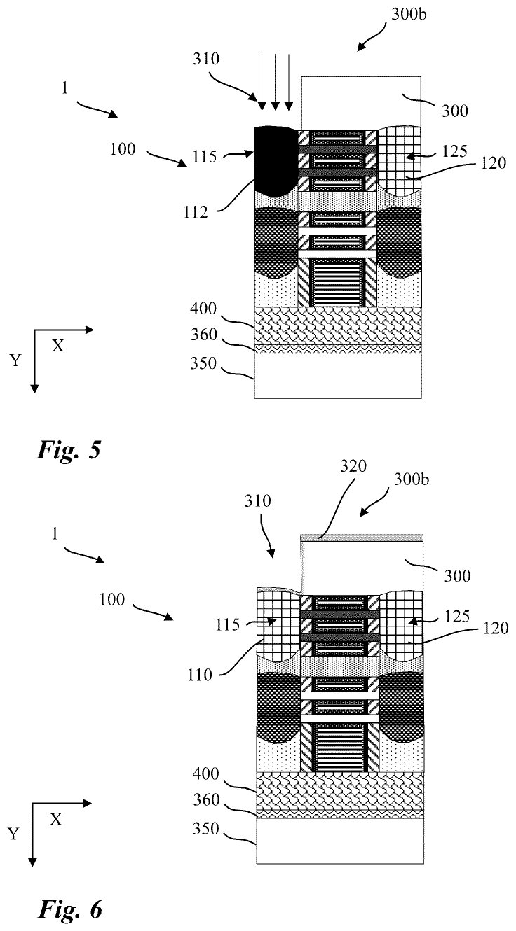

The first S/D body 110 may be processed from the opening 310 to form the replacement S/D body 112 (see e.g. FIG. 5) in the first S/D region 115. The processing of the first S/D body 110 may, as indicated above, aim at forming the replacement S/D body 112 having a second doping concentration different from the first doping concentration. In this way, an asymmetric transistor structure, e.g., a non-uniform transistor structure with asymmetric source drain doping may be formed.

FIG. 5 illustrates the structure 1 after the first S/D body 110 has been processed to form, in the first S/D region 115, the replacement S/D body 112. More specifically, the replacement S/D body 112 of FIG. 5 has been formed by increasing the doping concentration in the first S/D body 110. In other words, the material of the first S/D body 110 has been modified by increasing the doping concentration in the material of the first S/D body. The doping concentration of the first S/D body 110 may be increased by implanting dopants into the first S/D body 110, and/or by diffusing dopants into the first S/D body 110 as generally indicated by the arrows in FIG. 5. The doping concentration of the first S/D body 110 may be increased by implanting or diffusing P, As, Sb, Ga or B into the first S/D body 110. The doping concentration of the replacement S/D body 112 of FIG. 5 may lie in a part of the range of 1·1017-1·1022 dopants per cubic centimeter above the doping concentration of the first S/D body 110.

FIG. 6 illustrates the structure 1 of FIG. 4 after the structure 1 has been subjected to further processing steps prior to processing the first S/D body 110 to form the replacement S/D body 112. In FIG. 6, an insulating liner 320 covering the substrate and the exposed first S/D body 115 has been formed. The insulating liner 320 may be formed by (e.g., conformally) depositing a dielectric material such as, an insulating oxide or nitride, over the backside 300b of the substrate 300 and over the interior surfaces of the opening 310 including the exposed portions of the exposed first S/D body 110. The insulating liner 320 may include silicon dioxide or silicon nitride.

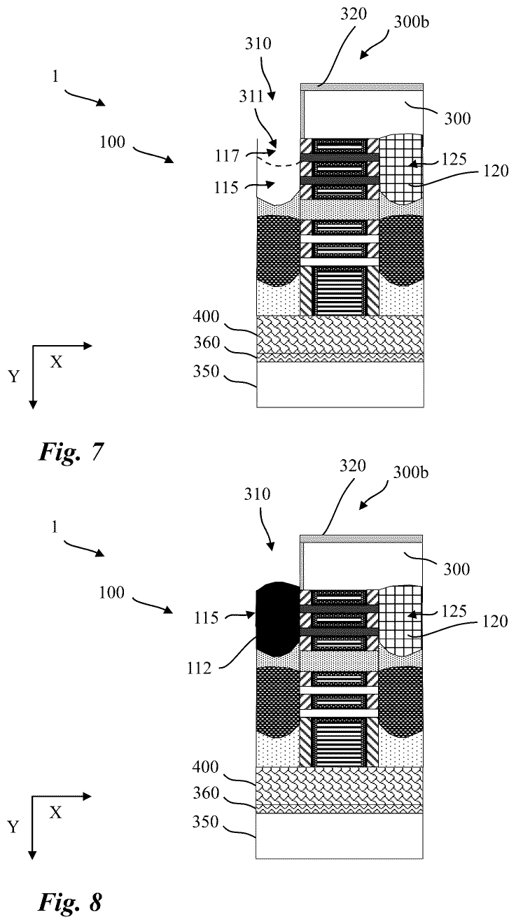

In FIG. 7, the insulating liner 320 has been opened in (e.g., via or from) the opening 310 in the substrate 300, thereby forming an opening 311 in the insulating liner 320. By opening the insulating liner 320 in the opening 310 of the substrate 300, the first S/D body 110 has been exposed via the openings 310 and 311. Part of the insulating liner 320 may be removed by a conventional pattering and etching process. For example, a patterned resist may be used as an etch mask for opening the insulating liner 320 in the opening 310 of the substrate 300.

Further, in FIG. 7, the first S/D body 110 has been substantially (e.g., completely) removed to form an S/D body cavity 117 the first S/D region 115. Alternatively, at least a portion of the first S/D body 110 (e.g., or at least a major portion of the first S/D body 110) may be removed, to form the S/D body cavity 117 in the first S/D region 115, as indicated by the hatched line in the S/D body cavity 117 of the first S/D region 115. The shape of the hatched line is schematic. For example, the S/D body cavity 117 may instead be formed in a center portion of the first S/D body 110 such that portions of the first S/D body 110 remain adjacent the channel layers 132 and inner spacers 150.

Now also turning to FIG. 8. FIG. 8 illustrates the structure 1 of FIG. 7. However, in FIG. 8, the structure of FIG. 7 has been subjected to further processing steps. In FIG. 8, doped S/D material has been epitaxially grown in the first S/D region 115. Hence, doped S/D material has been epitaxially grown via the opening in the insulating liner 320. That is, doped S/D material has been epitaxially grown in the S/D body cavity 117. Hence, the first S/D body has been processed from the opening in the insulating liner 320 to form a replacement S/D body 112 having a second doping concentration which is different from the first doping concentration. In this way, an asymmetric transistor structure, e.g., a non-uniform transistor structure with asymmetric source/drain doping has been formed. The S/D material may be doped with P, As, Sb, Ga or B. The doped S/D material may be grown by chemical vapor deposition (CVD) or atomic layer deposition (ALD) processes. The doping concentration of the replacement S/D body 112 of FIG. 8 may lie in the range of 1·1017-1·1022 dopants per cubic centimeter. The doped S/D material may comprise the same material or materials as the first S/D body but with a different doping concentration.

In case the first S/D body 110 has not been (e.g., completely) removed, and the doped S/D material has been grown on an exposed surface of the first S/D body 110, the formed replacement S/D body 112 will (e.g., in practice) in part be formed of the initial first S/D body 110 and in part be formed of the epitaxially grown doped S/D material. Further, the formed replacement S/D body 112 will have a doping concentration which is different from that of the first S/D body by the doped S/D material having a doping concentration being different from that of the first S/D body.

In FIG. 9, an S/D contact 114 has been formed on the replacement S/D body 112. Hence, the S/D contact 114 has been formed from the backside 300b of the substrate 300. The S/D contact 114 may be formed using conventional methods.

Now turning to FIG. 10, an alternative way of forming a semiconductor device according to example embodiments will be described while starting from structure 1 of FIG. 2. Thus, FIG. 10 illustrates the structure 1 of FIG. 2. However, in FIG. 10, the structure of FIG. 2 has been subjected to further processing steps. In FIG. 10, the substrate 300 has been removed underneath the transistor structure 100 to expose the first S/D body 110 and the second S/D body 120. The substrate 300 may be removed underneath the transistor structure 100 using (e.g., conventional) processes including grinding or CMP and/or etching, such as dry etching, wet etching, a gas chemical etch process like siconi or a certas type of process.

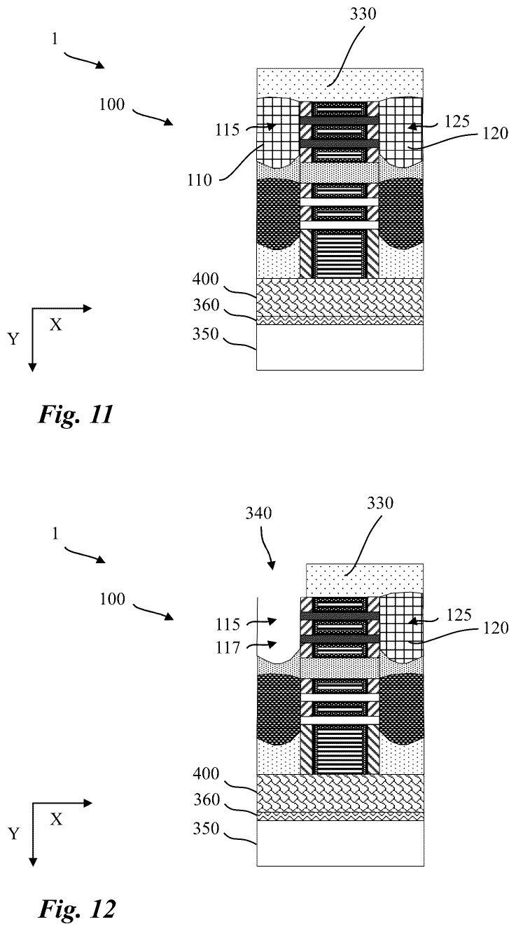

In FIG. 11, a bottom isolation layer 330 covering the first S/D body 110 and the second S/D body 120 has been formed. The bottom isolation layer 330 may be formed by e.g., depositing or growing silicon dioxide or silicon nitride such that the bottom isolation layer 330 covers the first S/D body 110 and the second S/D body as illustrated in FIG. 11. The bottom isolation layer 330 may for example be formed by CVD, ALD or physical vapor deposition (PVD).

In FIG. 12, an opening 340 has been formed in the bottom isolation layer 330 to expose the first S/D body 110. By forming the opening 340 in the bottom isolation layer 330 the first S/D body 110 has been exposed via the opening 340. The opening 340 in the bottom isolation layer 330 may formed by a (e.g., conventional) pattering and etching process. For example, a patterned resist may be used as an etch mask for forming the opening 340.

Further, in FIG. 12, the first S/D body 110 has been substantially (e.g., completely) removed. Thus, the removal of the first S/D body may result in that an S/D body cavity 117 is formed. The formation of the S/D body cavity 117 has been described above with respect to FIG. 7. Further, as described with respect to FIG. 7 alternatively, at least a portion of the first S/D body 110 (e.g., or at least a major portion of the first S/D body 110 may be removed) to form the S/D body cavity 117 in the first S/D region 115.

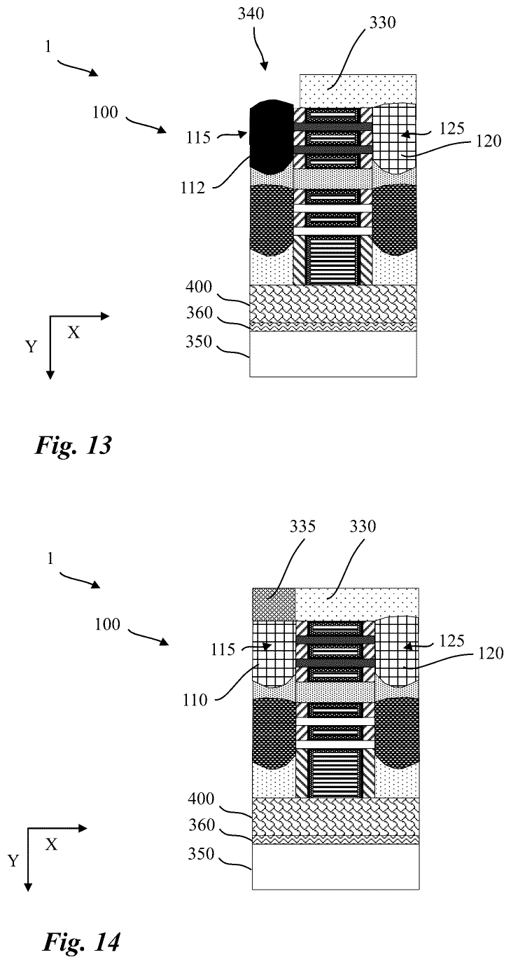

In FIG. 13, the first S/D body 110 has been processed from the opening 340 in the bottom isolation layer 330. More specifically, the first S/D body 110 may be processed as have been described above with respect to FIG. 8 to form the replacement S/D body 112 having a second doping concentration which is different from the first doping concentration. Further, an S/D contact 114 may be formed on the replacement S/D body 112 as has been described above with respect to FIG. 9.

Now also turning to FIG. 14, FIG. 14 illustrates a structure 1 similar to the structure 1 of FIG. 11. However, in FIG. 14, a dummy contact plug 335 is provided underneath the first S/D body 110 as illustrated in FIG. 14. The dummy contact plug 335 of FIG. 14 has been formed during front side processing taking place prior to the backside processing. By the provision of the dummy contact plug, an opening 340 corresponding to the opening 340 of FIG. 11 may be formed by removing the dummy contact plug 335. The opening 340 in the bottom isolation layer 330 may be formed by removing the dummy contact plug 335 provided underneath the first S/D body 110.

The dummy contact plug 335 may be formed during front side processing prior to forming the transistor structure 100, by e.g. forming a recess in the substrate 300, with a well-controlled overlay with respect to the S/D region 115, and forming the dummy contact plug 335 in the recess. The dummy contact plug 335 may be formed by a dummy material such as amorphous silicon, an epitaxial semiconductor material (e.g., Ge, Si or SiGe), a dielectric material, or more generally any suitable dummy material which may be removed selectively to the bottom isolation layer 330, and which is compatible (e.g., in terms of thermal budget) with the preceding steps of the frontside and backside-processing.

By the provision of the dummy contact plug 335, the opening 340 may be formed in a self-aligned manner with respect to the first S/D body 110.

In case the dummy contact plug 335 is recessed in the substrate 300, an opening 310 may be formed in the substrate 300 by removing the dummy contact plug 335. Hence, an opening 310 may be formed in the substrate, as illustrated in FIG. 4. In practice, the formation of such opening 310 may comprise thinning the substrate 300 to expose the dummy contact plug 335 provided underneath the first S/D body 110, and removing the dummy contact plug 335 to expose the first S/D body 110.

Once the opening 310 or the opening 340 has been formed, the structure 1 may be processed as have been described above with respect to FIG. 5, 8 or 13 to form the replacement S/D body 112 having a second doping concentration different from the first doping concentration. Further, an S/D contact 114 may be formed on the replacement S/D body 112 as have been described above in conjunction with FIG. 9.

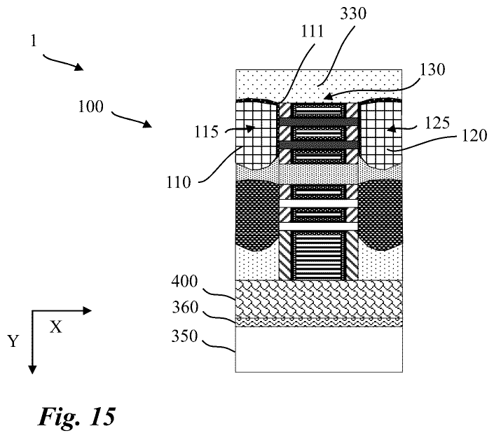

Now turning to FIG. 15, FIG. 15 illustrates a structure 1 highly similar to the structure 1 of FIG. 11. However, in FIG. 15, the first S/D body 110 comprises a semiconductor liner 111. As illustrated in FIG. 15, the semiconductor liner 111 is provided at least at an interface between the first S/D body 11 and the channel structure 130. The semiconductor liner 111 may for example also be provided underneath the first S/D body as illustrated in FIG. 15. The semiconductor liner 111 may be formed of a material different from a material of the first S/D body 110. The semiconductor liner 111 may for example be formed of silicon or silicon germanium having a low germanium content than the first S/D body 110. In this regard, when the semiconductor liner 111 is formed of silicon germanium, the germanium content may typically be lower than a germanium content of the first S/D body 110 in case also the first S/D body is formed of silicon germanium.

By the provision of the semiconductor liner 111 formed of a material different from a material of the first S/D body 110, the first S/D body 110 may be etched (e.g., selectively) with respect to the semiconductor liner 111. In practice, at least a portion (e.g., or at least a major portion) of the first S/D body 110 may be removed using an etching process of etching the material of the first S/D body selective to the material of the semiconductor liner 111. In this way, a source body cavity 117 corresponding to the source body cavity of FIG. 12 may be formed. Further, by the provision of the semiconductor liner 111 formed of a material different from a material of the first S/D body 110, the removal or partial removal of the first S/D body may be performed with a reduced risk of damaging the channel structure 130. By way of example, the semiconductor liner 111 may be formed by a silicon germanium material with a germanium concentration which differs from the material of the first S/D body by 10% or more (e.g., being at least 10% greater or smaller).

The present disclosure is not limited to the embodiments described above. Many modifications and variations are possible within the scope of the appended claims. For example, the replacement S/D body may comprise more than one material or material composition. In this regard, the replacement S/D body may comprise two or more layers having different material compositions. For example, the replacement S/D body may comprise two or more layers of SiGe with different Ge concentrations. Further, a dummy contact plug 335 may be used in coordination with a first S/D body comprising a semiconductor liner 111. Further, a dummy contact plug 335 may be used in coordination with an insulating liner or layer 320. Furthermore, an S/D contact 114 may be formed on any replacement S/D body 112 described above.

Moreover, after forming the replacement S/D body 112 and an S/D contact 114 in accordance with any of the above described approaches, additional backside processing steps may be applied to the structure 10. For example, the method may proceed with forming a backside interconnect structure for routing signals or power to the transistor structure 100, e.g. via the S/D contact 114, and to any further devices (e.g., CFETs) of the device structure 1. A backside interconnect structure may be formed using conventional techniques used in the BEOL for forming frontside interconnect structures, such as damascene processing.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for forming a semiconductor device, comprising:
performing frontside processing comprising forming
a transistor structure on a frontside of a substrate, the transistor structure comprising
a first source/drain body and
a second source/drain body located in a first and a second source/drain region, respectively, and
a channel structure between the first source/drain body and the second source/drain body, wherein the first source/drain body and the second source/drain body have a first doping concentration;
subsequent to the frontside processing, performing backside processing comprising:
exposing the first source/drain body from a backside of the substrate; and
processing the first source/drain body to form, in the first source/drain region, a replacement source/drain body having a second doping concentration different from the first doping concentration.

2. The method according to claim 1, wherein processing the first source/drain body comprises epitaxially growing doped source/drain material in the first source/drain region.

3. The method according to claim 2, wherein the doped source/drain material is grown on an exposed surface of the first source/drain body.

4. The method according to claim 2, wherein processing the first source/drain body further comprises
removing at least a portion the first source/drain body to form a source/drain body cavity in the first source/drain region, wherein the doped source/drain material subsequently is epitaxially grown in the source/drain body cavity.

5. The method according to claim 1, wherein the first source/drain body comprises a semiconductor liner provided at least at an interface between the first source/drain body and the channel structure, wherein the semiconductor liner is formed of a material different from a material of the first source/drain body.

6. The method according to claim 5, when dependent on claim 4, wherein the at least a portion of the first source/drain body is removed using an etching process etching the material of the first source/drain body selective to the material of the semiconductor liner.

7. The method according to claim 1, wherein exposing the first source/drain body comprises thinning the substrate from the backside.

8. The method according to claim 1, wherein exposing the first source/drain body comprises forming an opening in the substrate underneath the first source/drain body to expose the first source/drain body, wherein the first source/drain body is processed from the opening in the substrate.

9. The method according to claim 8, further comprising:
subsequent to forming the opening in the substrate, forming an insulating liner covering the substrate and the exposed first source/drain body; and
opening the insulating liner in the opening in the substrate to expose the first source/drain body,
wherein the first source/drain body is processed from the opening in the insulating liner.

10. The method according to claim 9, wherein processing the first source/drain body comprises epitaxially growing doped source/drain material in the first source/drain region, and wherein the doped source/drain material is epitaxially grown via the opening in the insulating liner.

11. The method according to claim 10, wherein processing the first source/drain body comprises
epitaxially growing doped source/drain material in the first source/drain region, and
removing at least a portion the first source/drain body to form a source/drain body cavity in the first source/drain region, wherein the doped source/drain material subsequently is epitaxially grown in the source/drain body cavity, wherein the at least a portion of the first source/drain body is removed by etching from the opening in the insulating liner.

12. The method according to claim 1, wherein exposing the first source/drain body comprises:
removing the substrate underneath the transistor structure to expose the first source/drain body and the second source/drain body;
forming a bottom isolation layer covering the first source/drain body and the second source/drain body; and
forming an opening in the bottom isolation layer to expose the first source/drain body;
wherein the first source/drain body is processed from the opening in the bottom isolation layer.

13. The method according to claim 12, wherein the opening in the bottom isolation layer is formed by removing a dummy contact plug provided underneath the first source/drain body.

14. The method according to claim 1, wherein processing the first source/drain body comprises increasing the doping concentration in the first source/drain body, and wherein increasing the doping concentration comprises:
implanting dopants into the first source/drain body, and/or
diffusing dopants into the first source/drain body.

15. The method according to claim 1, wherein the method further comprises forming a source/drain contact on the replacement source/drain body.

16. The method according to claim 2, wherein the replacement source/drain body is formed with a higher doping concentration as compared to the first source/drain body by growing the doped source/drain material having a doping concentration higher than the first doping concentration.

17. The method according to claim 2, wherein the replacement source/drain body is formed with a lower doping concentration as compared to the first source/drain body by growing the doped source/drain material having a doping concentration lower than the first doping concentration.

18. The method according to claim 9, wherein processing the first source/drain body comprises epitaxially growing doped source/drain material in the first source/drain region, and wherein the insulating liner inhibits the doped source/drain material from growing at the substrate while being epitaxially grown via the opening in the insulating liner.

19. The method according to claim 9, wherein the insulating liner is used as an epitaxy mask inhibiting deposition of source/drain material in regions other than the first source/drain region.

20. The method according to claim 9, wherein the insulating liner is used as an etch mask when etching the first source/drain body.
